(19) United States
(12) Patent Application Publication
(10) Pub. No.: US 2006/0216546 A1
(43) Pub. Date: Sep. 28, 2006

(54) Organic electroluminescent element

(75) Inventor: Hiroshi Tada, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/387,890

(22) Filed: Mar. 24, 2006

(30) Foreign Application Priority Data
Mar. 28, 2005 (JP) 2005-093317

(51) Int. Cl. H01L 51/54; H05B 33/12

(52) U.S. Cl. 428/690; 428/917; 428/212; 313/504; 313/506

(57) ABSTRACT

The present invention provides an organic electroluminescent element including, between an anode and a cathode, at least a luminescent layer and a hole blocking layer that is adjacent to the cathode side of the luminescent layer, wherein the luminescent layer includes a phosphorescent material and a host material, the hole blocking layer includes a phosphorescent material and an electron transport material, the phosphorescent material contained in the luminescent layer and hole blocking layer is the same, and the ionization potential IP (ET) of the electron transport material contained in the hole blocking layer is greater than the ionization potential IP (EM) of the phosphorescent material by 1 eV or more.

### CROSS-REFERENCE TO RELATED APPLICATION

This application claims priority under 35 USC 119 from Japanese Patent Application No. 2005-093317, the disclosure of which is incorporated by reference herein.

### BACKGROUND OF THE INVENTION

1. Field of the Invention

The present invention relates to an organic electroluminescent element capable of emitting light by converting electric energy into light (hereinafter also referred to as an “organic EL element”, “luminescent element”, or “EL element”).

2. Description of the Related Art

Various display elements have been intensively researched and developed recently, and an organic electroluminescent (EL) element has received attention as a promising display element among such display elements because light can be emitted at high luminance at low voltage.

The organic electroluminescent element has a pair of electrodes and a luminescent layer or a plurality of organic layers including the luminescent layer between the pair of electrodes, and makes use of luminescence from excitons generated by recombination of electrons injected from a cathode and holes injected from an anode in the luminescent layer, or makes use of luminescence from excitons of other molecules generated by energy transfer from the generated excitons.

It has been proposed to obtain blue luminescence of high efficiency by providing a structure having a hole transport layer doped with a phosphorescent material and an electron transport layer doped with the same phosphorescent material (see, for example, Japanese Patent Application National Publication No. 2004-522264, the disclosure of which is incorporated by reference herein).

However, organic electroluminescent elements using a phosphorescent material (phosphorescent elements) are low in durability, particularly in the case of blue or green luminescence, and improvement of durability thereof is demanded.

### SUMMARY OF THE INVENTION

The present invention has been made in view of the above circumstances and provides an organic electroluminescent element excellent in driving durability without lowering luminescent characteristics.

In the light of the above circumstances, the present inventor has intensively researched and completed the invention.

An aspect of the invention provides an organic electroluminescent element comprising, between an anode and a cathode, at least a luminescent layer and a hole blocking layer that is adjacent to the cathode side of the luminescent layer. The luminescent layer comprises a phosphorescent material and a host material. The hole blocking layer comprises a phosphorescent material and an electron transport material. The phosphorescent material contained in the luminescent layer and the hole blocking layer is the same. The ionization potential IP (ET) of the electron transport material contained in the hole blocking layer is greater than the ionization potential IP (EM) of the phosphorescent material by 1 eV or more.

### DETAILED DESCRIPTION OF THE INVENTION

The organic electroluminescent element of the present invention (sometimes referred to as an “organic EL element”) is specifically described below.

The organic electroluminescent element of the invention is an organic electroluminescent element having, between an anode and a cathode, at least a luminescent layer and a hole blocking layer that is adjacent to the cathode side of the luminescent layer. The luminescent layer includes a phosphorescent material and a host material, and the hole blocking layer includes a phosphorescent material and an electron transport material. The phosphorescent material contained in the luminescent layer and the hole blocking layer is the same. The ionization potential IP (ET) of the electron transport material contained in the hole blocking layer is greater than the ionization potential IP (EM) of the phosphorescent material by 1 eV or more.

The organic electroluminescent element of the invention, having such a configuration, is excellent in driving durability without lowering luminescent characteristics (high external quantum efficiency).

The hole blocking layer of the invention has a function of enhancing luminescent efficiency by preventing leaking of holes and excitons from the luminescent layer.

Generally, an electron transport material is used in the hole blocking layer. When the element is driven, since holes and excitons leak out from the luminescent layer to the electron transport material, the electron transport material is decomposed. However, when a phosphorescent material is contained in the hole blocking layer, the decomposition of the electron transport material can be prevented, and hence the element durability is improved.

In the invention, it has been found that an organic electroluminescent element excellent in driving durability without lowering luminescent characteristics can be obtained by designing the electroluminescent element such that the ionization potential IP (ET) of the electron transport material is greater than the ionization potential IP (EM) of the phosphorescent material by 1 eV or more in order to prevent injection of holes into the electron transport material; and by using the same phosphorescent material in the hole blocking layer and the luminescent layer in order to prevent change in the luminescent color of the element due to the phosphorescent material that is contained in the hole blocking layer also emitting light when the element is driven.

The ionization potential is defined in terms of a value measured at room temperature in air by using an ultraviolet photoelectric analyzer AC-1 (manufactured by Riken Keiki Co., Ltd.). The measuring principle of AC-1 is described in Chihaya Adachi et al., Yuki Hakumaku Sigoto Kansu Data Shu (Work Function Data of Organic Thin Film), CMC (2004), the disclosure of which is incorporated by reference herein.

Materials of which ionization potential exceed 6.2 eV may be measured by UPS (vacuum ultraviolet photoelectron spectroscopy) owing to the problem of measuring range.

The Configuration of the organic electroluminescent element of the invention will be described below.

The luminescent element of the invention has a pair of electrodes, i.e. a cathode and an anode, and, between the pair of electrodes, at least a luminescent layer and a hole blocking layer that is adjacent to the cathode side of the luminescent layer. The cathode and the anode are preferably formed on a substrate. Other organic compound layers may be disposed between the luminescent layer and the anode, and between the hole blocking layer and the cathode. In view of the nature of the luminescent element, at least one of the anode and the cathode is preferably transparent. Usually, the anode is transparent.

As for the layer constitution of the organic electroluminescent element of the invention, in a preferred embodiment, a hole transport layer, a luminescent layer, and a hole blocking layer are disposed in this order from the anode side. Further, a charge blocking layer or the like may be disposed between the hole transport layer and the luminescent layer.

In the invention, each of the layers disposed between the pair of electrodes, including the luminescent layer, may also be generally referred to as an “organic compound layer.”

The constituents of the organic electroluminescent element of the invention are described in detail below.

<Substrate>

The substrate which can be used in the invention is preferably a substrate which does not scatter or attenuate the light emitted from the luminescent layer. Specific examples thereof include inorganic materials such as yttria-stabilized zirconia (YSZ), and glass; polyesters such as polyethylene terephthalate, polybutylene phthalate, and polyethylene naphthalate; and organic materials such as polystyrene, polycarbonate, polyethersulfone, polyallylate, polyimide, polycycloolefin, norbornene resins, and poly(chlorotrifluoroethylene).

For example, when glass is used for the substrate, it is preferable to use a non-alkali glass as the substrate material, in order to reduce ions eluting from the glass. Also, when soda lime glass is used, it is preferable to use one having a barrier coat such as silica or the like. In the case of using organic materials, preferred are those having excellent heat resistance, dimensional stability, solvent resistance, electrical insulating property and processability.

The shape, structure, size and the like of the substrate are not particularly limited and can be selected appropriately in accordance with the intended use, purpose and the like of the luminescent element. In general, the substrate is preferably plate-shaped. The structure of the substrate may be either a monolayer structure or a laminated structure. Further, the substrate may be made of a single material or of two or more materials.

The substrate may be colorless transparent, or colored transparent, and is preferably colorless transparent in terms of no scattering or attenuation of the light emitted from the light emitted from the luminescent layer.

The substrate can be provided with a moisture penetration resistance layer (gas barrier layer) on the surface or the back surface.

As for the material for the moisture penetration resistance layer (gas barrier layer), inorganic substances such as silicon nitride, silicon oxide or the like are suitably used. The moisture penetration resistance layer (gas barrier layer) can be formed, for example, by high frequency sputtering or the like.

When a thermoplastic substrate is used, a hard coat layer, an undercoat layer or the like may be further provided, if necessary.

<Anode>

The anode may usually serve as an electrode that supplies holes to the organic compound layers. There is no limitation on the shape, structure, size or the like thereof, and the material can be appropriately selected from known electrode materials depending on the intended use and purpose of the luminescent element. As described above, the anode is typically formed as a transparent anode.

Examples of the material of the anode that are suitable include metals, alloys, metal oxides, electroconductive compounds or mixtures thereof, and preferred is a material having a work function of 4.0 eV or more. Specific examples of the anode material include electroconductive metal oxides such as tin oxide doped with antimony or fluorine (ATO, FTO), tin oxide, zinc oxide, indium oxide, indium tin oxide (ITO), and indium zinc oxide (IZO); metals such as gold, silver, chromium, and nickel; as well as mixture or laminates of such metals and electroconductive metal oxides; inorganic electroconductive materials such as copper iodide, and copper sulfate; organic electroconductive materials such as polyaniline, polythiophene, and polypyrrole; and laminates of these substances with ITO. Preferred among these is an electroconductive metal oxide, and particularly preferred is ITO in the aspects of productivity, high electroconductivity and transparency.

The anode can be formed on the substrate according to a method appropriately selected, in consideration of the suitability to the material constituting the anode, for example, from wet methods such as a printing method and a coating method, physical methods such as a vacuum deposition method, a sputtering method and an ion plating method, and chemical methods such as CVD and a plasma CVD. For example, when ITO is selected as the material for anode, formation of the anode can be carried out by a DC sputtering or high frequency sputtering method, a vacuum deposition method, an ion plating method or the like.

In the organic electroluminescent element of the invention, the position of the anode to be formed is not particularly limited and the anode can be formed in any part of the luminescent element selected according to the intended use and purpose thereof. It is preferred that the anode is formed on the substrate. In this case, the anode may be formed on the entire surface of one side of the substrate, or in a part of such surface.

Moreover, patterning in the formation of an anode may be carried out by means of chemical etching such as photolithography or the like, or by means of physical etching such as laser or the like. Further, it may be also carried out by vacuum deposition or sputtering with masking, or may be carried out by the lift-off method or printing method.

The thickness of the anode can be appropriately selected in accordance with the material constituting the anode and thus cannot be indiscriminately defined. It is usually from 10 nm to 50 μm, and preferably from 50 nm to 20 μm.

The resistance value of the anode is preferably 10³ Ω/sq or less, and more preferably 10² Ω/sq or less. When the anode is transparent, it may be colorless transparent, or colored transparent. In order to obtain luminescence from the transparent anode side, the transmittance is preferably 60% or more, and more preferably 70% or more.

In addition, a transparent anode is described in detail in “Tohmeidodenmaku No Shintenkai (Development of Transparent Conductive Films)” supervised by Yutaka Sawada, CMC Inc. (1999), the disclosure of which is incorporated by reference herein, and the description thereof is applicable to the invention. In case of using a plastic substrate with low heat resistance, it is preferable to employ ITO or IZO and form a transparent anode film at a low temperature of 150° C. or less.

<Cathode>

The cathode may usually serve as an electrode that injects electrons to the organic compound layers. There is no limitation on the shape, structure, size or the like thereof, and the material can be appropriately selected from known electrode materials depending on the intended use and purpose of the luminescent element.

Examples of the material of the cathode include metals, alloys, metal oxides, electroconductive compounds or mixtures thereof, and preferred is a material having a work function of 4.5 eV or less. Specific examples of the cathode material include alkali metals (e.g., Li, Na, K, Cs, etc.), alkaline earth metals (e.g., Mg, Ca, etc.), gold, silver, lead, aluminum, sodium-potassium alloys, lithium-aiuminum alloys, magnesium-silver alloys, indium, rare earth metals such as ytterbium. They may be used individually, or from the viewpoint of achieving both stability and electron injection property, they may be suitably used in combination of two or more types.

Among these, as for the material constituting the cathode, alkali metals or alkaline earth metals are preferred from the viewpoint of the electron injection property, and materials mainly comprising aluminum are preferred from the viewpoint of excellent storage stability.

The materials mainly comprising aluminum are, for example, aluminum itself, alloys comprising aluminum and 0.01 to 10% by mass of alkali metals or alkaline earth metals (e.g., lithium-aluminum alloys, magnesium-aluminum alloys, etc.), and mixtures thereof.

In addition, the materials for the cathode are described in detail in JP-A Nos. 2-15595 and 5-121172, the disclosures of which are incorporated by reference herein, and the materials described in these gazettes are applicable to the invention.

The method for formation of a cathode is not particularly limited and may be carried out according to a known method. The cathode can be formed according to a method appropriately selected, in consideration of the suitability to the material constituting the cathode, for example, from wet methods such as a printing method and a coating method, physical methods such as a vacuum deposition method, a sputtering method and an ion plating method, and chemical methods such as CVD and a plasma CVD method. For example, in the case of selecting a metal or the like as the material for the cathode, the formation can be carried out by simultaneous or successive sputtering of one, or two or more types thereof.

Patterning in the formation of the cathode may be carried out by means of chemical etching such as photolithography or the like, or by means of physical etching such as laser or the like. Further, it may be also carried out by vacuum deposition or sputtering with masking, or may be carried out by the lift-off method or the printing method.

In the invention, the position of the cathode to be formed is not particularly limited, and the cathode may be formed all over the organic compound layer, or in a part thereon.

Further, a dielectric layer of 0.1 to 5 nm in thickness, comprising a fluoride, oxide or the like of an alkali metal or an alkaline earth metal may be inserted between the cathode and the organic compound layer. This dielectric layer can be considered as a type of electron injecting layer. The dielectric layer can be formed by, for example, vacuum deposition, sputtering, ion plating or the like.

The thickness of the cathode can be appropriately selected in accordance with the material constituting the cathode and thus cannot be indiscriminately defined. It is usually from 10 nm to 5 μm, and preferably from 50 nm to 1 μm. The cathode may be transparent or opaque. A transparent cathode can be formed by forming a film of a cathode material having a thickness of 1 to 10 nm and further laminating thereon a transparent electroconductive material such as ITO or IZO.

<Organic Compound Layer>

The organic electroluminescent element of the invention has a luminescent layer and a hole blocking layer that is adjacent to the cathode side of the luminescent layer, and may also contain other layers as stated above.

Examples of other layers include a hole transport layer, an electron transport layer, a charge blocking layer, a hole injecting layer, an electron-injecting layer, and others.

The layer adjacent to the luminescent layer on the anode side may be a hole injecting layer, a hole transport layer, an electron blocking layer or the like, and the hole transport layer is preferable. Details of these layers are described below.

—Formation of Organic Compound Layer—

In the organic electroluminescent element of the invention, each of the organic compound layers can be suitably formed by a dry film forming method such as vapor deposition or sputtering, a transfer method, a printing method and the like.

—Luminescent Layer—

The luminescent layer is a layer having the function of emitting light by accepting holes from the anode, the hole injecting layer or the hole transport layer and accepting electrons from the cathode, the electron injecting layer or the electron transport layer upon application of an electric field, and providing a site for recombination of the holes and the electrons.

The luminescent layer according to the invention contains a host material and a dopant such as a phosphorescent material. The host material, which is not particularly limited, is preferably a charge transport material.

The luminescent layer may be a single layer or two or more layers.

The phosphorescent material contained in the luminescent layer is in general a complex containing a transition metal atom or a lanthanoid atom.

The transition metal atom is not particularly limited. Preferable examples thereof include ruthenium, rhodium, palladium, tungsten, rhenium, osmium, iridium and platinum. The transition metal is more preferably rhenium, iridium or platinum.

Examples of the lanthanoid atom include lanthanum, cerium, praseodymium, neodymium, samarium, europium, gadolinium, terbium, dysprosium, holmium, erbium, thulium, ytterbium and lutetium. Among these lanthanoid atoms, neodymium, europium and gadolinium are preferred.

Examples of the ligand of the complex include ligands described in G. Wilkinson et al, Comprehensive Coordination Chemistry, Pergamon Press (1987); H. Yersin, “Photochemistry and Photophysics of Coordination Compounds,” Springer-Verlag (1987); Akio Yamamoto, “Yukikinzokukagaku—Kiso to Oyo—(Organometallic Chemistry—Principles and Applications—),” Shokabo (1982); the disclosures of which are incorporated by reference herein, and the like.

Specifically, the ligand is preferably a halogen ligand (preferably a chlorine ligand), a nitrogen-containing heterocyclic ligand (e.g., phenyl pyridine, benzoquinoline, quinolinol, bipyridyl, phenanthroline, etc.), a diketone ligand (e.g., acetylacetone, etc.), a carboxylic acid ligand (e.g., acetic acid ligand, etc.), a carbon monoxide ligand, an isonitrile ligand, or a cyano ligand, and more preferably a nitrogen-containing heterocyclic ligand. The complex may have one transition metal atom, or may be a so-called multinuclear complex having two or more of such atoms. It may also contain metal atoms of different types simultaneously.

The phosphorescent material may be used either singly or in combination of two or more thereof.

The phosphorescent material is preferably contained in the luminescent layer in an amount of 0.1 to 20% by mass, more preferably 0.5 to 15% by mass, and particularly preferably 2 to 10% by mass.

The host material contained in the luminescent layer of the invention is not particularly limited. Examples of the host material include any material having a carbazole skeleton, a diarylamine skeleton, a pyridine skeleton, a pyradine skeleton, a triazine skeleton, or an aryl silane skeleton, and among these, from the viewpoint of element durability, a material having a carbazole skeleton (or carbazole group) is preferred.

The T₁ level of the host material (energy level of the lowest excited multiplet state) is preferably higher than the T₁ level of the dopant material. By co-depositing the host material and the dopant material, a luminescent layer in which the dopant material is doped in the host material can be appropriately formed.

The host material is preferably contained in the luminescent layer in an amount of 50 to 99.9% by mass, more preferably 70 to 99.9% by mass, and particularly preferably 80 to 99% by mass.

The thickness of luminescent layer is not particularly limited, and is usually 1 nm to 500 nm, preferably 5 nm to 200 nm, and more preferably 10 nm to 100 nm.

—Hole Blocking Layer—

The hole blocking layer is a layer having a function of preventing holes which are transported from the anode side to the luminescent layer, from passing through to the cathode side. In the invention, the hole blocking layer is provided as an organic compound layer that is adjacent to the luminescent layer on the cathode side.

The hole blocking layer contains at least a phosphorescent material and an electron transport material.

The ionization potential IP (ET) of the electron transport material contained in the hole blocking layer is greater than the ionization potential IP (EM) of the phosphorescent material by 1 eV or more in order to prevent leaking of holes from the luminescent layer and enhance luminescent efficiency.

Also from the view point of preventing leaking of holes from the luminescent layer and enhancing luminescent efficiency, the ionization potential IP (ET) of electron transport material contained in the hole blocking layer is preferablyl 6.3 eV or more, and more preferably 6.5 eV or more.

The electron transport material is not particularly limited as long as it is selected in relation to the phosphorescent material. Examples the electron transport material include azoles (for example, oxazole, oxadiazole, imidazole, triazole, thiazole, thiadizole, and their derivatives (including condensates)), azines (for example, pyridine, pyrimidine, triazine, and their derivatives (including condensates)), organic silanes (for example, silole, aryl substituted silane, and their derivatives (including condensates)), fluorine substituted aromatic hydrocarbon rings, various metal complexes represented by metal complex of 8-quinolinol, and metal complex having metal fluorocyanine, benzoxazole or benzothiazole as a ligand, and their derivatives.

The electron transport material used in the invention is preferably an azole compound or an azine compound, and more preferably a compound represented by formula (A-1) or (B-1) below.

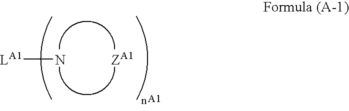

In formula (A-1), Z^{A1} represents an atomic group necessary for forming a nitrogen-containing heterocycle, L^{A1} is a linking group, and n^{A1} is an integer of 2 or more.

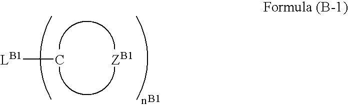

In formula (B-1), Z^{B1} represents an atomic group necessary for forming an aromatic hydrocarbon ring or an aromatic heterocycle, L^{B1} is a linking group, and n^{B1} is an integer of 2 or more.

The compound represented by formula (A-1) is explained.

In formula (A-1), L^{A1} is a linking group. The linking group represented by L^{A1} is preferably a linking group formed by a single bond, a carbon atom, a silicon atom, a nitrogen atom, a phosphorus atom, a sulfur atom, an oxygen atom, a boron atom, a germanium atom or the like, more preferably a single bond, a carbon atom, a silicon atom, a boron atom, an oxygen atom, a sulfur atom, a germanium atom, an aromatic hydrocarbon ring, or an aromatic heterocycle, still more preferably a carbon atom, a silicon atom, an aromatic hydrocarbon ring, or an aromatic heterocycle, yet still more preferably a di- or higher-valent aromatic hydrocarbon ring, a di- or higher-valent aromatic heterocycle, or a carbon atom, further preferably a di- or higher-valent aromatic hydrocarbon ring or a di- or higher-valent aromatic heterocycle, and particularly preferably a 1,3,5-benzene triyl group, a 1,2,5,6-benzene tetrayl group, a 1,2,3,4,5,6-benzene hexayl group, a 2,2′-dimethyl-4,4′-biphenylene group, a 2,4,6-pyridine triyl group, a 2,3,4,5,6-pyridine pentayl group, a 2,4,6-pyrimidine triyl group, a 2,4,6-triazine triyl group, or a 2,3,4,5-thiophene tetrayl group.

Specific examples of the linking group represented by L^{A1} include the following.

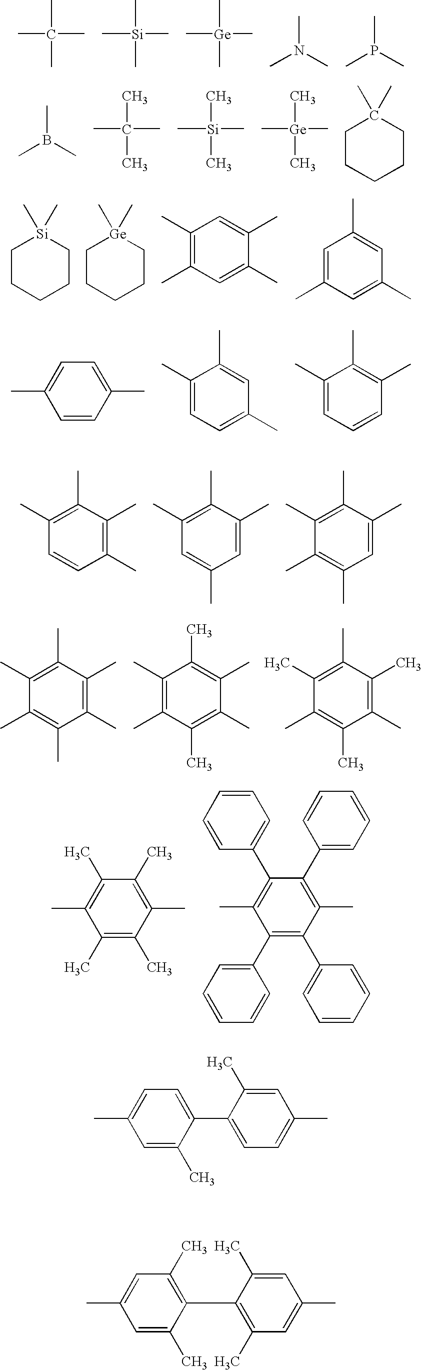

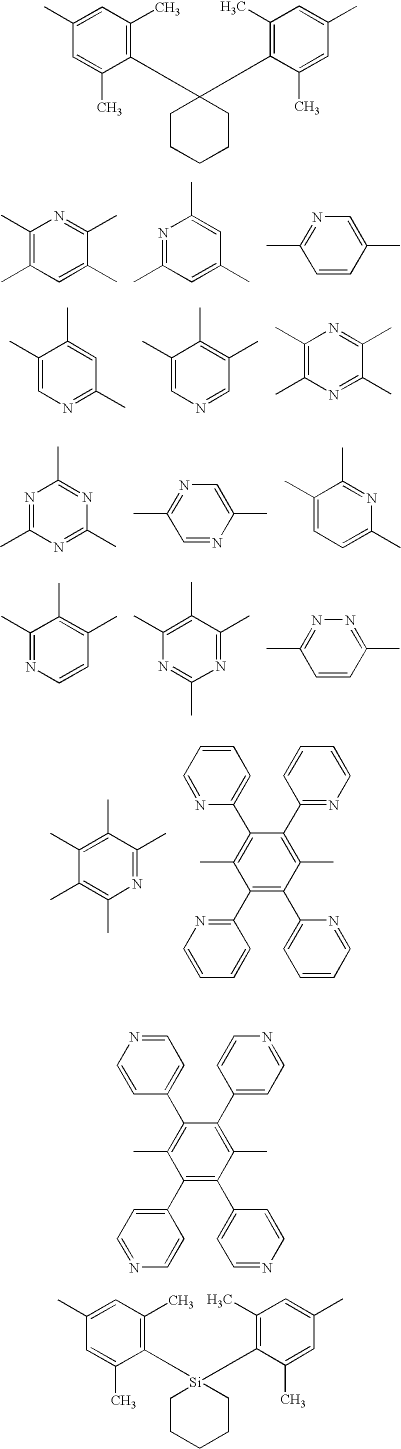

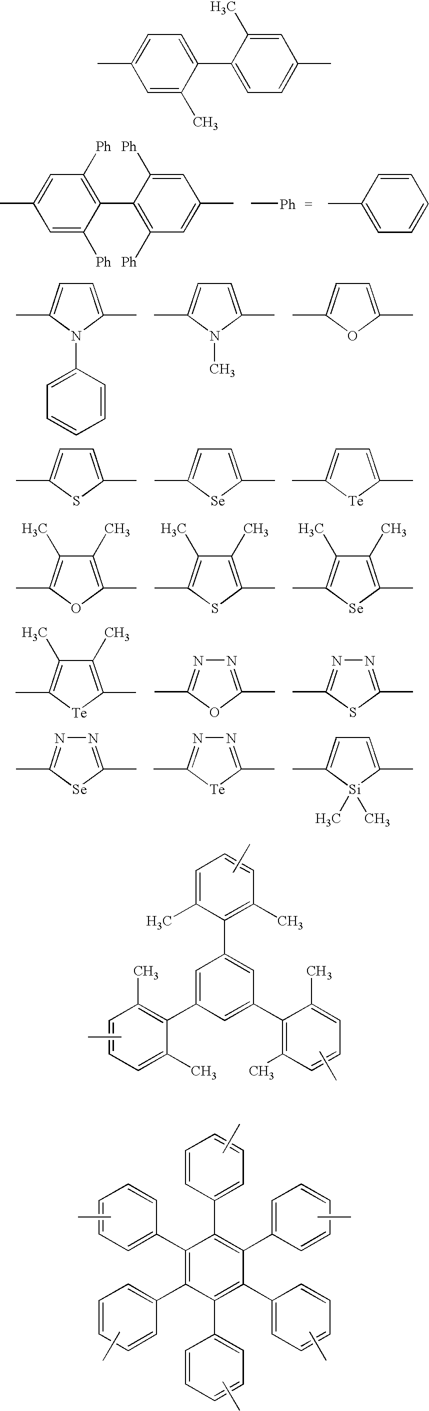

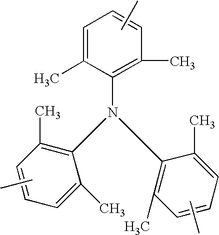

L^{A1} may further have a substituent. Examples of the substituent include an alkyl groups (preferably having 1 to 30 carbon atoms, more preferably 1 to 20 carbon atoms, still more preferably 1 to 10 carbon atoms, for example, methyl, ethyl, iso-propyl, tert-butyl, n-octyl, n-decyl, n-hexadecyl, cyclopropyl, cyclopentyl, cyclohexyl), alkeny groups (preferably having 2 to 30 carbon atoms, more preferably 2 to 20 carbon atoms, still more preferably 2 to 10 carbon atoms, for example, vinyl, allyl, 2-butenyl, 3-pentenyl), alkynyl groups (preferably 2 to 30 carbon atoms, more preferably 2 to 20 carbon atoms, still more preferably 2 to 10 carbon atoms, for example, propargyl, 3-pentynyl), aryl groups (preferably having 6 to 30 carbon atoms, more preferably 6 to 20 carbon atoms, still more preferably 6 to 12 carbon atoms, for example, phenyl, p-methyl phenyl, naphthyl, anthranyl), amino groups (preferably having 0 to 30 carbon atoms, more preferably 0 to 20 carbon atoms, still more preferably 0 to 10 carbon atoms, for example, amino, methyl amino, dimethyl amino, diethyl amino, dibenzyl amino, diphenyl amino, ditolyl amino), alkoxy groups (preferably having 1 to 30 carbon atoms, more preferably 1 to 20 carbon atoms, still more preferably 1 to 10 carbon atoms, for example, methoxy, ethoxy, butoxy, 2-ethyl hexyloxy), aryl oxy groups (preferably having 6 to 30 carbon atoms, more preferably 6 to 20 carbon atoms, still more preferably 6 to 12 carbon atoms, for example, phenyloxy, 1-naphthyloxy, 2-naphthyloxy), heterocycle oxy groups (preferably having 1 to 30 carbon atoms, more preferably 1 to 20 carbon atoms, still more preferably 1 to 12 carbon atoms, for example, pyridyloxy, pyraldyloxy, pyrimidyloxy, quinolyloxy), acyl groups (preferably having 1 to 30 carbon atoms, more preferably 1 to 20 carbon atoms, still more preferably 1 to 12 carbon atoms, for example, acetyl, benzoyl, formyl, pivaloyl), alkoxy carbonyl groups (preferably having 2 to 30 carbon atoms, more preferably 2 to 20 carbon atoms, still more preferably 2 to 12 carbon atoms, for example, methoxy carbonyl, ethoxy carbonyl), aryloxy carbonyl groups (preferably having 7 to 30 carbon atoms, more preferably 7 to 20 carbon atoms, still more preferably 7 to 12 carbon atoms, for example, phenyloxy carbonyl), acyloxy groups (preferably having 2 to 30 carbon atoms, more preferably 2 to 20 carbon atoms, still more preferably 2 to 10 carbon atoms, for example, acetoxy, benzoyloxy), acylamino groups (preferably having 2 to 30 carbon atoms, more preferably 2 to 20 carbon atoms, still more preferably 2 to 10 carbon atoms, for example, acetylamino, benzoylamino), alkoxy carbonyl amino groups (preferably having 2 to 30 carbon atoms, more preferably 2 to 20 carbon atoms, still more preferably 2 to 12 carbon atoms, for example, methoxy carbonyl amino), aryloxy carbonyl amino groups (preferably having 7 to 30 carbon atoms, more preferably 7 to 20 carbon atoms, still more preferably 7 to 12 carbon atoms, for example, phenyloxy carbonyl amino), sulfonyl amino groups (preferably having 1 to 30 carbon atoms, more preferably 1 to 20 carbon atoms, still more preferably 1 to 12 carbon atoms, for example, methane sulfonyl amino, benzene sulfonyl amino), sufamoyl groups (preferably having 0 to 30 carbon atoms, more preferably 0 to 20 carbon atoms, still more preferably 0 to 12 carbon atoms, for example, sulfamoyl, methyl sulfamoyl, dimethyl sufamoyl, phenyl sulfamoyl), carbamoyl groups (preferably having 1 to 30 carbon atoms, more preferably 1 to 20 carbon atoms, still more preferably 1 to 12 carbon atoms, for example, carbamoyl, methyl carbamoyl, diethyl carbamoyl, phenyl carbamoyl), alkylthio groups (preferably having 1 to 30 carbon atoms, more preferably 1 to 20 carbon atoms, still more preferably 1 to 12 carbon atoms, for example, methyl thio, ethyl thio), arylthio groups (preferably having 6 to 30 carbon atoms, more preferably 6 to 20 carbon atoms, still more preferably 6 to 12 carbon atoms, for example, phenyl thio), heterocyclic thio groups (preferably having 1 to 30 carbon atoms, more preferably 1 to 20 carbon atoms, still more preferably 1 to 12 carbon atoms, for example, pyridyl thio, 2-benzimisolyl thio, 2-benzoxazolyl thio, 2-benzthiazolyl thio), sulfonyl groups (preferably having 1 to 30 carbon atoms, more preferably 1 to 20 carbon atoms, still more preferably 1 to 12 carbon atoms, for example, mesyl, tosyl), sulfinyl groups (preferably having 1 to 30 carbon atoms, more preferably 1 to 20 carbon atoms, still more preferably 1 to 12 carbon atoms, for example methane sulfinyl, benzene sulfinyl), ureide groups (preferably having 1 to 30 carbon atoms, more preferably 1 to 20 carbon atoms, still more preferably 1 to 12 carbon atoms, for example, ureide, methyl ureide, phenyl ureide), amide phosphate groups (preferably having 1 to 30 carbon atoms, more preferably 1 to 20 carbon atoms, still more preferably 1 to 12 carbon atoms, for example, amide diethyl phosphate, amide phenyl phosphate), a hydroxy group, a mercapto group, halogen atoms (for example, a fluorine atom, a chlorine atom, a bromine atom, an iodine atom), a cyano group, a sulfo group, a carboxyl group, a nitro group, a hydroxamic group, a sulfino group, a hydrozino group, an imino group, heterocyclic groups (preferably having 1 to 30 carbon atoms, more preferably 1 to 12 carbon atoms, and further having one or more hetero atoms (for example, an oxygen atom, a sulfur atom, etc.), for example, imidazolyl, pyridyl, quinolyl, furyl, thienyl, piperidyl, morpholino, benzoxazolyl, benzimidazolyl, benzthiazolyl, carbazolyl group, and azepinyl), silyl groups (preferably having 3 to 40 carbon atoms, more preferably 3 to 30 carbon atoms, still more preferably 3 to 24 carbon atoms, for example, trimethyl silyl, triphenyl silyl), and silyl oxy groups (preferably having 3 to 40 carbon atoms, more preferably 3 to 30 carbon atoms, still more preferably 3 to 24 carbon atoms, for example, trimethyl silyloxy, triphenyl silyloxy).

These substituents may be further substituted. Substituents which can be introduced to these substituents are each preferably an alkyl group, an aryl group, a heterocyclic group, a halogen atom, or a silyl group, and more preferably an alkyl group, an aryl group, a heterocyclic group, or a halogen atom, and still more preferably an alkyl group, an aryl group, and an aromatic heterocycle group. These substituents each may be selected from the examples of the substituents which can be introduced to L^{A1}, and the preferred range is also the same as that of the substituents which can be introduced to L^{A1}.

Z^{A1} represents an atomic group necessary for forming a nitrogen-containing heterocycle, and the nitrogen-containing heterocycle formed by Z^{A1} may be either a single ring or condensed ring in which two or more rings are condensed. The nitrogen-containing heterocycle formed by Z^{A1} is preferably a nitrogen-containing heterocycle of 5 to 8 members, more preferably a nitrogen-containing heterocycle of 5 to 7 members, still more preferably an aromatic nitrogen-containing heterocycle of 5 or 6 members, and particularly preferably an aromatic nitrogen-containing heterocycle of 5 members. A plurality of nitrogen-containing heterocycles formed by Z^{A1} connected to L^{A1} may be either same or different.

Specific examples of the nitrogen-containing heterocycle formed by Z^{A1} include a pyrrole ring, indole ring, oxazole ring, oxadiazole ring, thiazole ring, thiazaizole ring, aza indole ring, carbazole ring, carboline ring (Norharmann ring), imidazole ring, benzoimidazole ring, imidazopyridine ring, purin ring, pyrazole ring, indazole ring, aza indazole ring, triazole ring, tetrazole ring, azepine ring, iminostilbene ring (dibenzoazepine ring), tribenzoazepine ring, phenothiazine ring, and phenoxazine ring. The nitrogen-containing heterocycle formed by Z^{A1} is preferably an oxadiazole ring, triazole ring, imidazole ring, benzoimidazole ring, or imidazopyridine ring, and more preferably a benzoimidazole ring or imidazopyridine ring.

Z^{A1} may further form a condensed ring together with another ring, and may have a substituent. The substituent which can be introduced to Z^{A1} may be, for example, selected from the examples of the substituent which can be introduced to L^{A1} in formula (A-1) listed above, and the preferred range is also the same as that of the substituent which can be introduced to L^{A1} in formula (A-1).

n^{A1} is an integer of 2 or more, preferably 2 to 8, and more preferably 2 to 6.

The compound represented by formula (B-1) is explained.

In formula (B-1), L^{B1} is a linking group. Examples of the linking group L^{B1} include the specific examples of the linking group L^{A1} in formula (A-1) listed above. L^{B1} is preferably a single bond, a di- or higher-valent aromatic hydrocarbon ring, a di- or higher-valent aromatic heterocycle, a carbon atom, a nitrogen atom, or a silicon atom, more preferably a di- or higher-valent aromatic hydrocarbon ring or a di- or higher-valent aromatic heterocycle, and further preferably a 1,3,5-benzene triyl group, a 1,2,5,6-benzene tetrayl group, a 1,2,3,4,5,6-benzene hexayl group, a 2,2′-dimethyl-4,4′-biphenylene group, a 2,4,6-pyridine triyl group, a 2,3,4,5,6-pyridine pentayl group, a 2,4,6-pyrimidine triyl group, a 2,4,6-triazine triyl group, a 2,3,4,5-thiophene tetrayl group, a carbon atom, a nitrogen atom, or a silicon atom.

L^{B1} may further have a substituent, and the substituent may be, for example, selected from the examples of the substituent which can be introduced to L^{A1} in formula (A-1) listed above, and the preferred range is also the same as that of the substituent which can be introduced to L^{A1}.

Z^{B1} represents an atomic group necessary for forming an aromatic hydrocarbon ring or aromatic heterocycle, and the aromatic hydrocarbon ring or aromatic heterocycle formed by Z^{B1} may be either a single ring or condensed ring in which two or more rings are condensed. A plurality of the aromatic hydrocarbon rings or aromatic heterocycles formed by Z^{B1} connected to L^{B1} may be either same or different.

The aromatic hydrocarbon ring formed by Z^{B1} has preferably 6 to 30 carbon atoms, more preferably 6 to 20 carbon atoms, and still more preferably 6 to 12 carbon atoms, and preferred examples include a benzene ring, naphthalene ring, anthracene ring, phenanthrene ring, pyrene ring, and triphenylene ring, and preferably a benzene ring, naphthalene ring, phenanthrene ring, and triphenylene ring.

The aromatic heterocycle formed by Z^{B1} is a heterocycle of single ring or condensed ring in which two or more rings are condensed, and preferably has 1 to 20 carbon atoms, more preferably 2 to 12 carbon atoms, and still more preferably 2 to 10 carbon atoms. The heterocycle is preferably an aromatic heterocycle having at least one of nitrogen atom, oxygen atom, and sulfur atom. Specific examples of the heterocycle formed by Z^{B1} include a pyridine ring, quinoline ring, isoquinoline ring, acridine ring, phenanthridine ring, puteridine ring, pyradine ring, quinosaline ring, pyrimidine ring, quinazoline ring, pyridadine ring, sinnoline ring, phthaladine ring, triazine ring, oxazole ring, benzoxazole ring, thiazole ring, benzothiazole ring, imidazole ring, benzimidazole ring, pyrazole ring, indazole ring, isoxazole ring, benzoisoxazole ring, isothiazole ring, benzisothiazole ring, oxadiazole ring, thiadiazole ring, triazole ring, tetrazole ring, furan ring, benzofuran ring, thiophene ring, benzothiophene ring, pyrrole ring, indole ring, imidazopyridine ring, carbazole ring, and phenanthroline ring. The heterocycle formed by Z^{B1} is preferably a pyridine ring, quinoline ring, isoquinoline ring, acridine ring, phenanthridine ring, pyradine ring, quinoxaline ring, pyrimidine ring, quinazoline ring, pyridazine ring, phthaladine ring, triazine ring, imidazole ring, benzimidazole ring, pyrazole ring, indazole ring, oxadiazole ring, triazole ring, imidazopyridine ring, carbazole ring, or phenanthroline ring, more preferably a pyridine ring, quinoline ring, isoquinoline ring, pyradine ring, quinoxaline ring, pyrimidine ring, quinazoline ring, pyridazine ring, phthaladine ring, triazine ring, imidazole ring, benzimidazole ring, oxadiazole ring, triazole ring, imidazopyridine ring, or phenanthroline ring, still more preferably benzimidazole ring, oxadiazole ring, triazole ring, imidazopyridine ring, or phenanthroline ring, and particularly preferably a benzimidazole ring or imidazopyridine ring.

The aromatic hydrocarbon ring or aromatic heterocycle formed by Z^{B1} may further form a condensed ring together with another ring, and may have a substituent. The substituent may be, for example, selected from the examples of the substituent which can be introduced to L^{A1} in formula (A-1) listed above, and the preferred range is also the same as that of the substituent which can be introduced to L^{A1}.

n^{B1} is an integer of 2 or more, preferably 2 to 8, and more preferably 2 to 6.

The compound represented by formula (A-1) or formula (B-1) of the invention may be a low molecular weight compound, or may be an oligomer compound or polymer compound (weight-average molecular weight (as polystyrene) is preferably 1000 to 5000000, more preferably 2000 to 1000000, and still more preferably 3000 to 1000000). The compound of the invention is preferably a low molecular weight compound.

Specific examples of the compound represented by formula (A-1) or formula (B-1) of the invention are given below, but the invention is not limited to these compounds alone.

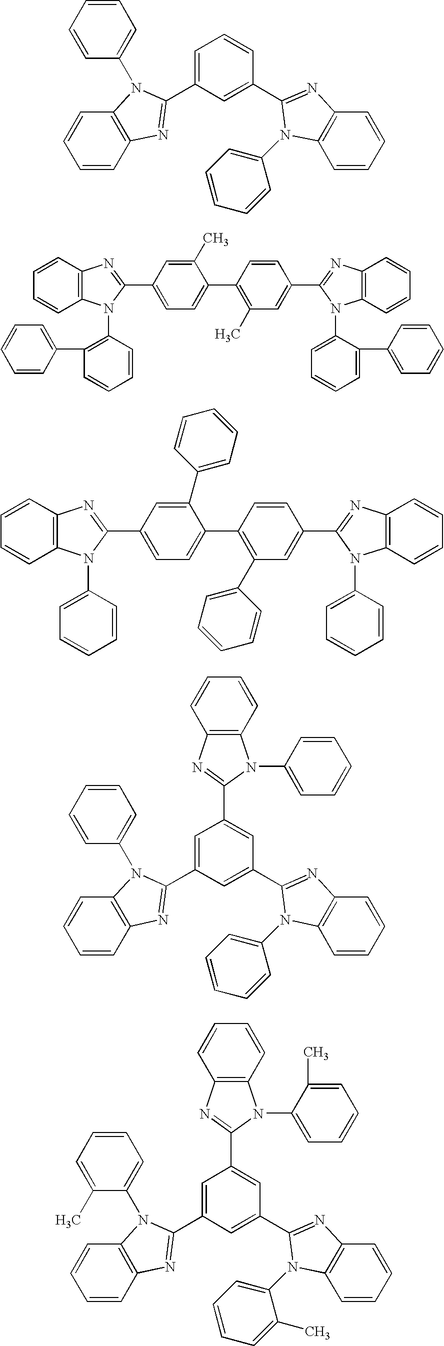

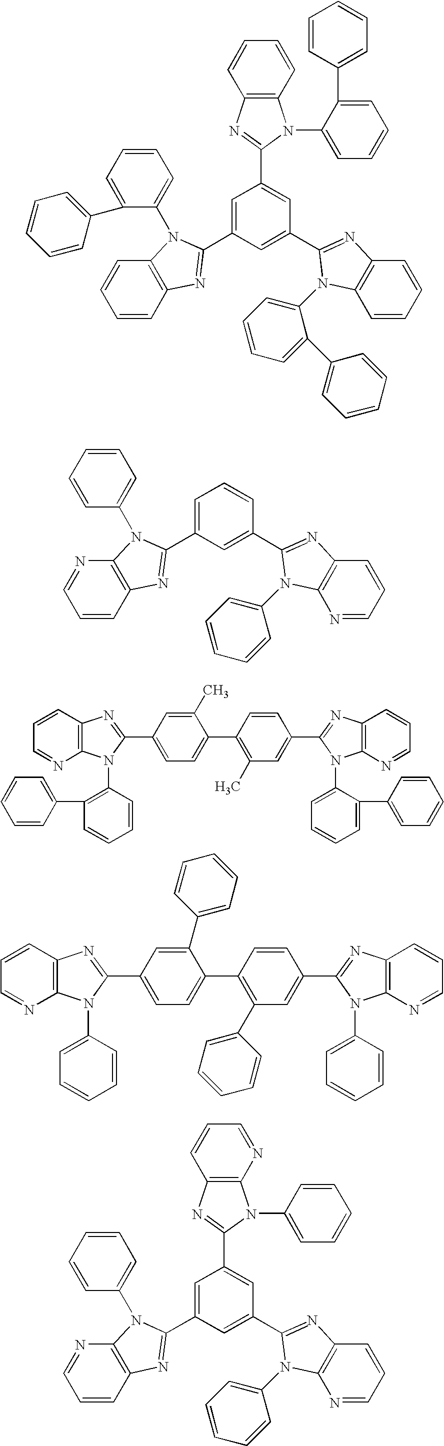

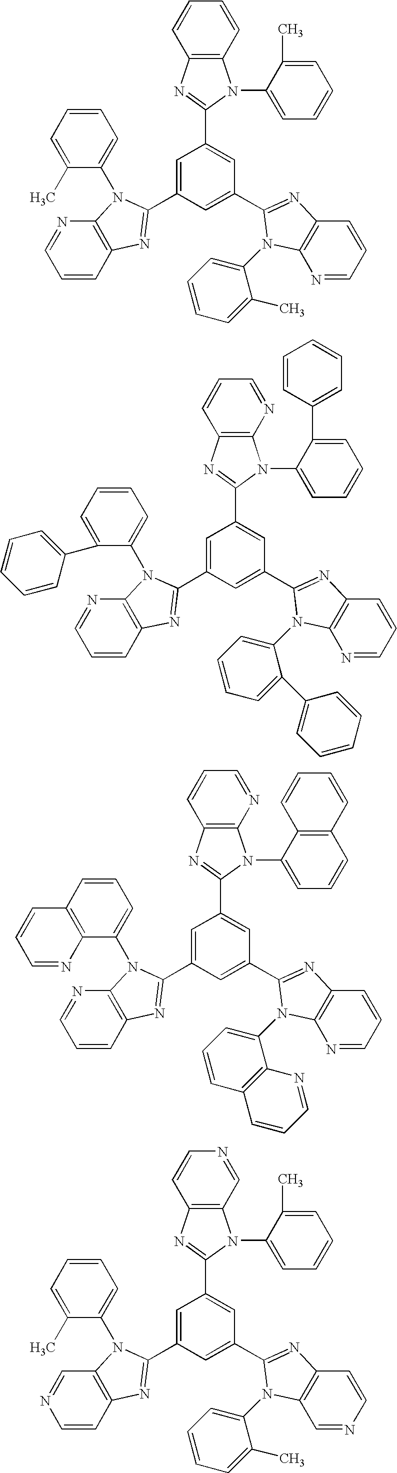

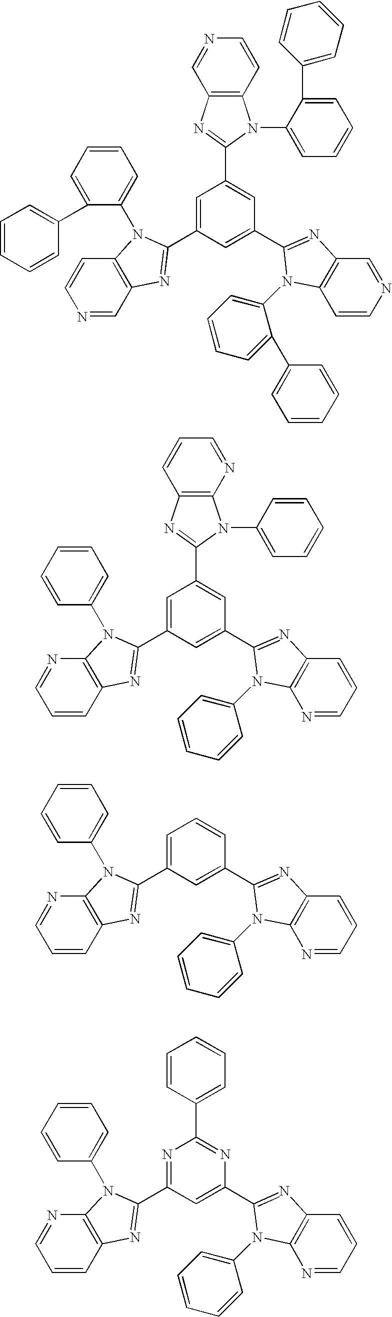

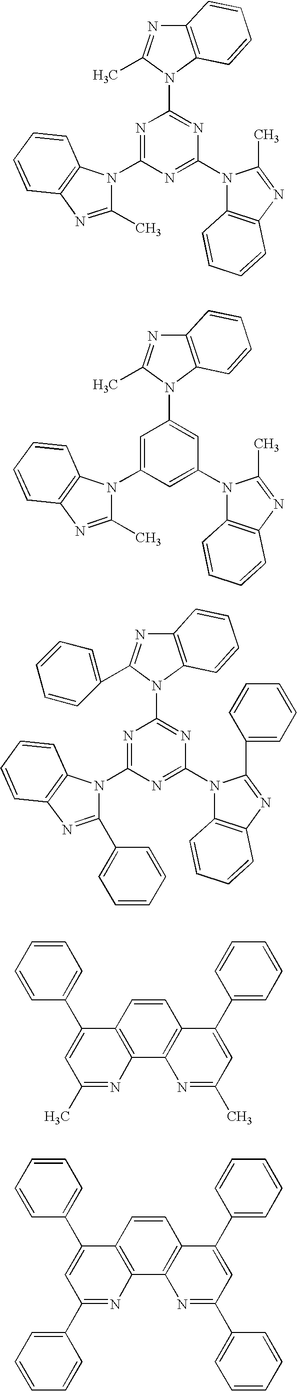

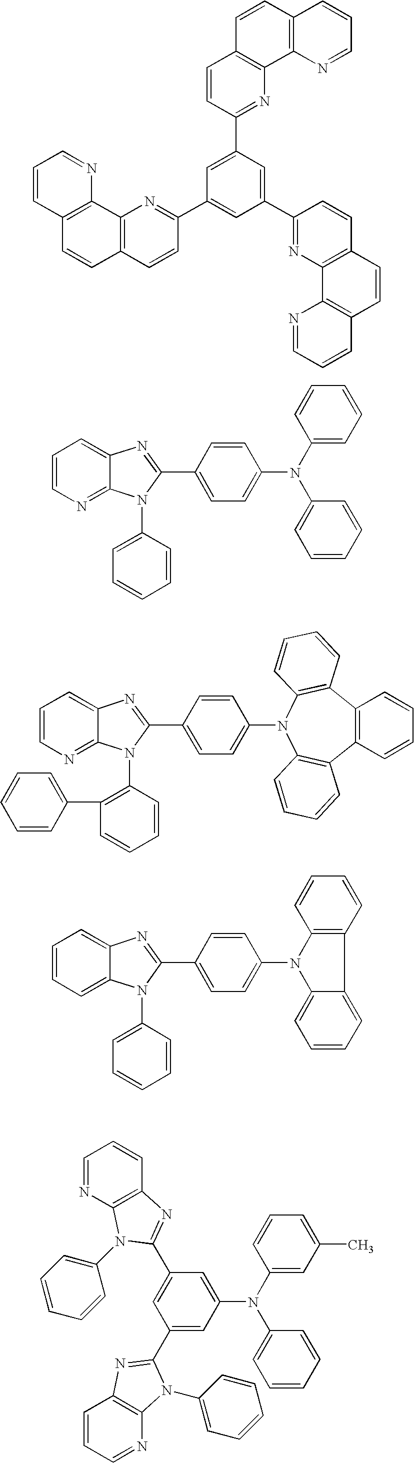

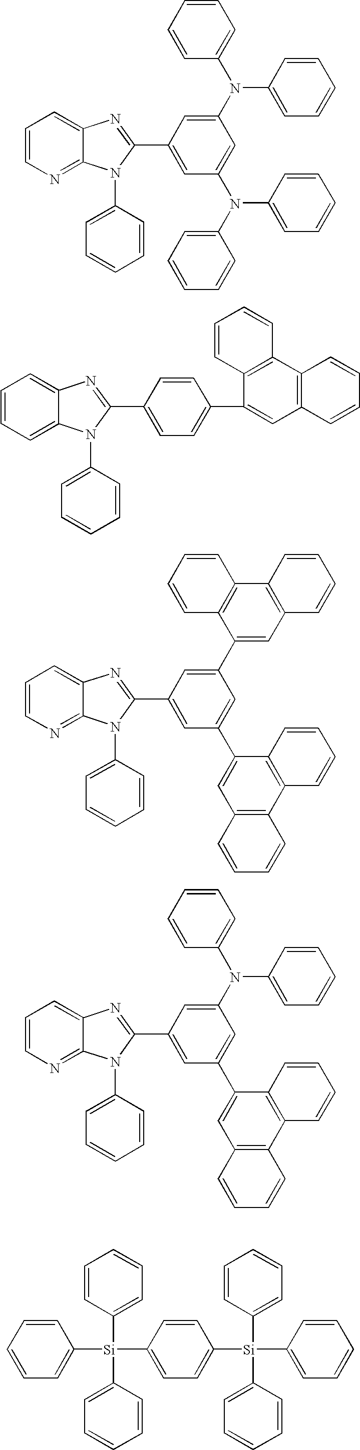

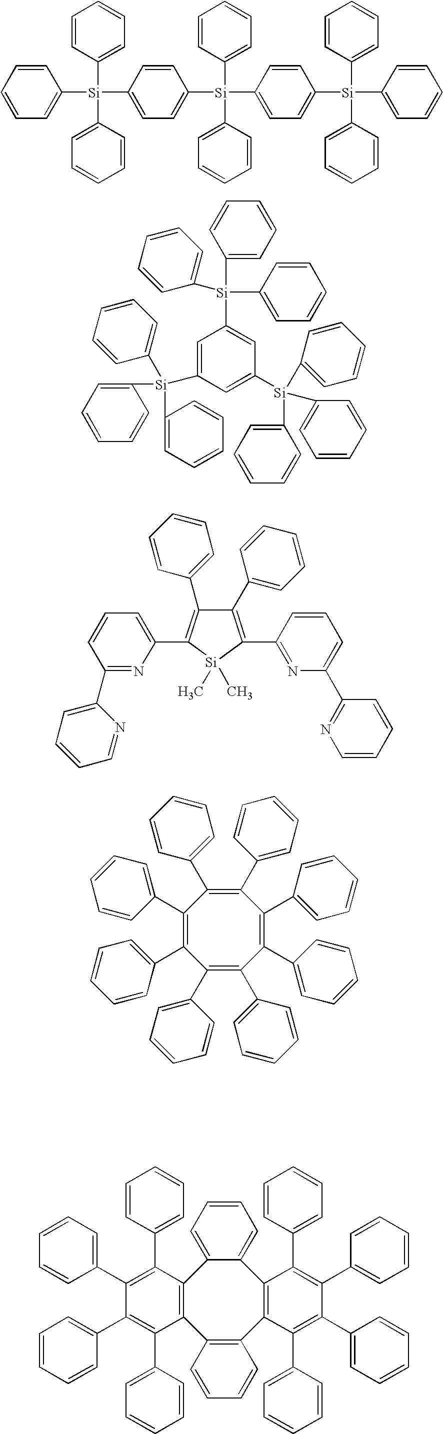

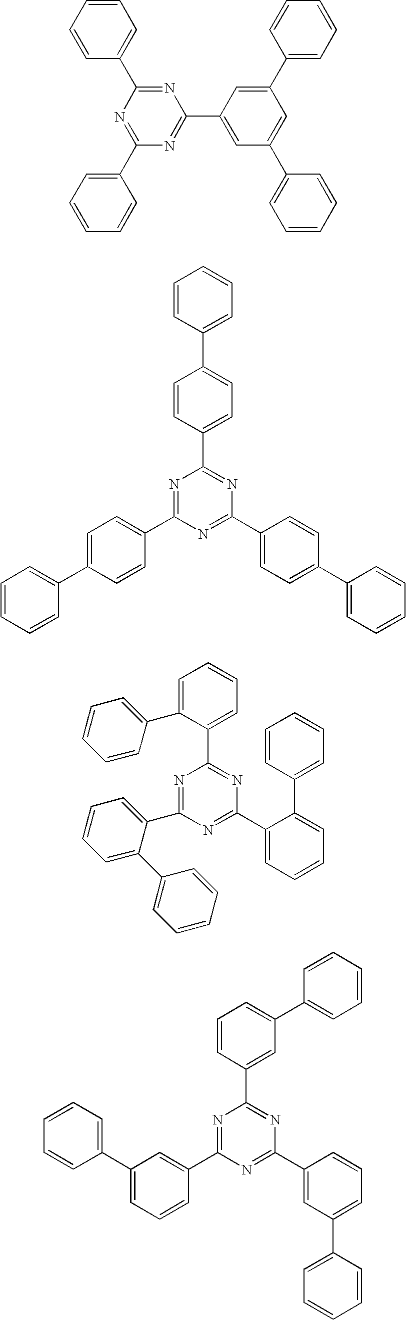

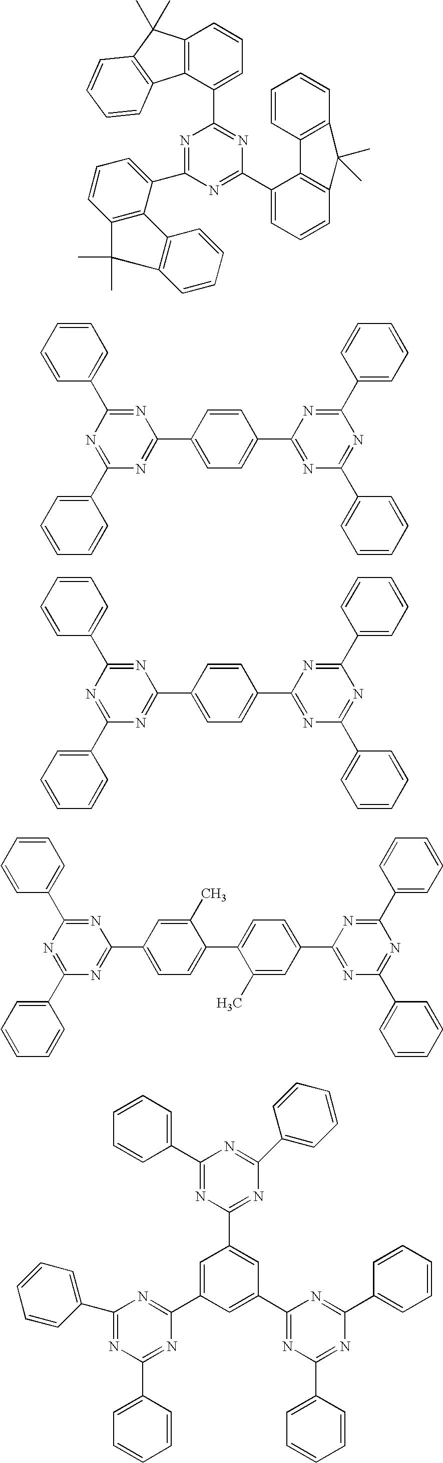

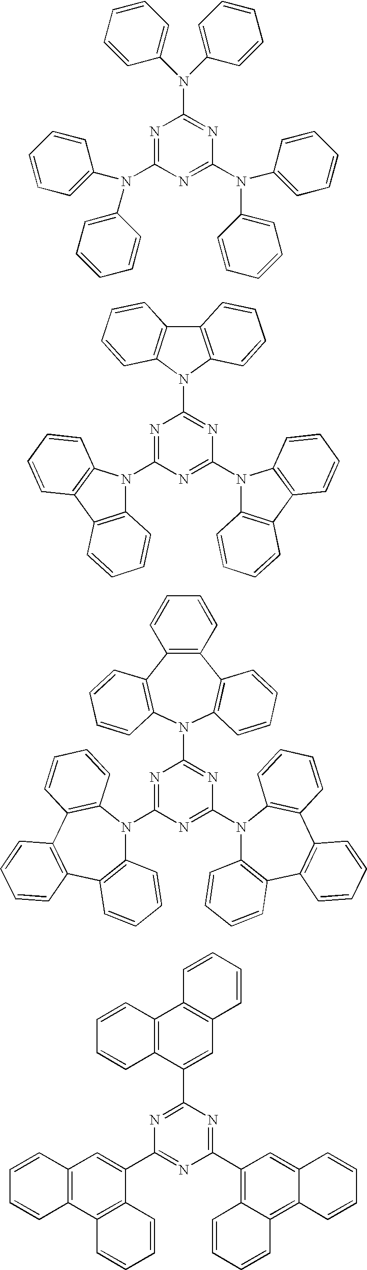

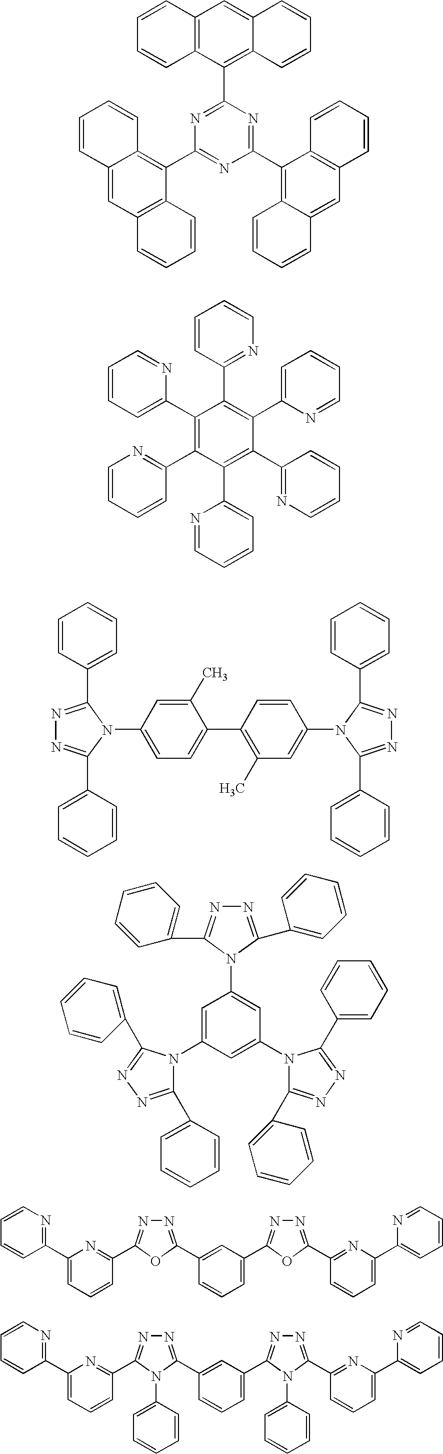

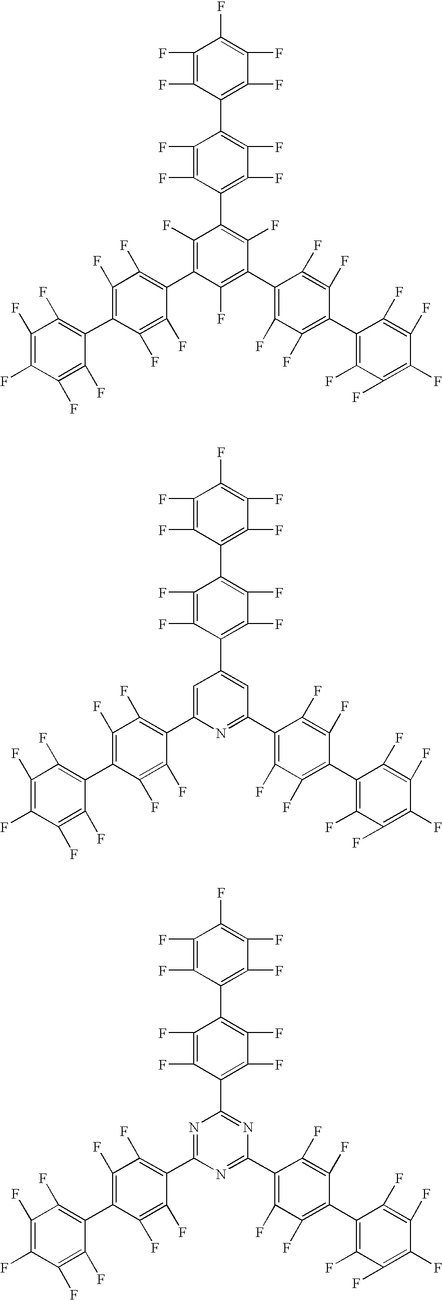

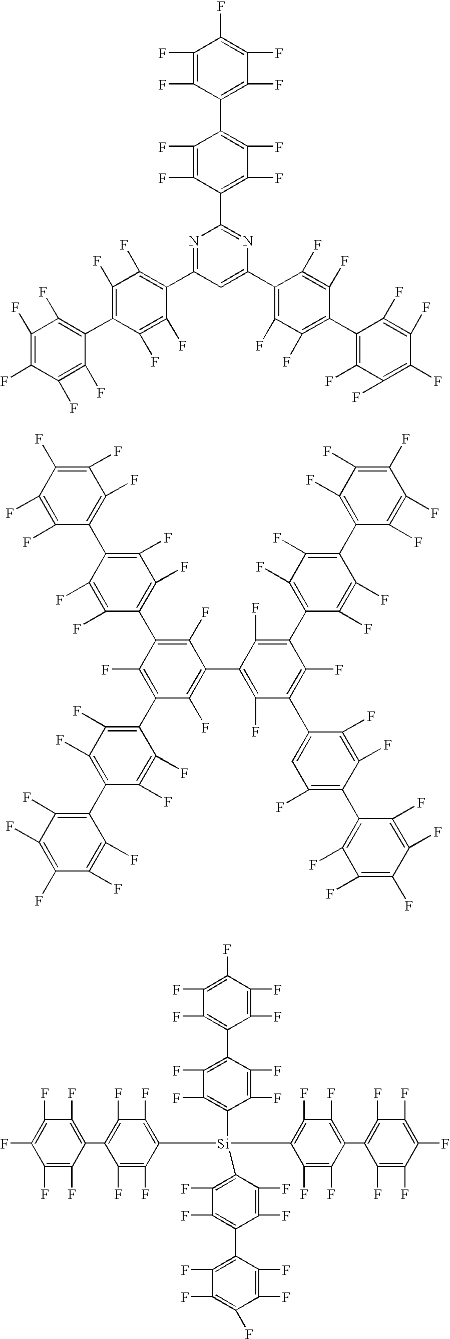

The electron transport material used in the hole blocking layer of the invention is preferably a material having three or more nitrogen atoms.

The electron transport material used in the hole blocking layer of the invention may be used either singly or in combination of two or more thereof.

The phosphorescent material is preferably contained in the hole blocking layer of the invention in an amount of 0.1 to 30% by mass, and more preferably 0.5 to 15% by mass.

The electron transport material is preferably contained in the hole blocking layer in an amount of 50 to 99.9% by mass, more preferably 70 to 99.9% by mass, and still more preferably 80 to 99% by mass.

In an embodiment, the hole blocking layer of the invention is preferably composed of the electron transport material and the phosphorescent material only, and in another embodiment, the hole blocking layer may further contain other materials.

The electron mobility of the electron transport material used in hole blocking layer of the invention is preferably 1×10⁻⁵ cm²/Vs or more from the viewpoint of sufficient electron injection into luminescent layer, and more preferably 1×10⁻⁴ cm²/Vs or more.

The electron mobility of the electron transport material can be determined by the TOF (time of flight) method, and the electron mobility in the invention refers to the value determined by the TOF method.

—Hole Injecting Layer and Hole Transport Layer—

The hole injecting layer and the hole transport layer are layers having the function of accepting holes from the anode or the anode side and transporting them to the cathode side. Specifically, the hole injecting layer and the hole transport layer are preferably layers containing a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidene-based compound, a porphyrin-based compound, an organic silane derivative, carbon or the like. The thicknesses of the hole injecting layer and the hole transport layer are each preferably 50 nm or less, from the viewpoint of lowering the driving voltage.

The thickness of the hole transport layer is preferably from 5 to 50 nm, and more preferably from 10 to 40 nm. Also, the thickness of the hole injecting layer is preferably from 0.5 to 50 nm, and more preferably from 1 to 40 nm.

The hole injecting layer and the hole transport layer may be of single-layered structure comprising one, or two or more types of the aforementioned materials, or may be of a multilayered structure consisting of a plurality of layers having the same composition or different compositions.

From the viewpoint of lowering the driving voltage of the element, the organic EL element of the invention may contain an electron-accepting dopant in the hole injecting layer or the hole transport layer. Any material such as an inorganic compound or an organic compound may be used as the electron-accepting dopant contained in the hole injecting layer or the hole transport layer as long as it has electron-accepting properties and is capable of oxidizing organic compounds.

Specific examples thereof among inorganic compounds include metal halides such as ferric chloride, aluminum chloride, gallium chloride, indium chloride and antimony pentachloride, and metal oxides such as vanadium pentoxide and molybdenum trioxide.

Preferable examples thereof among organic compounds include compounds having a nitro group, a halogen, a cyano group, a trifluoromethyl group or the like as a substituent thereof, quinone compounds, acid anhydride compounds, and fullerenes.

Preferable examples thereof further include compounds described in JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643, the disclosures of which are incorporated by reference herein, and the like.

These electron-accepting dopants may be used singly or in combination of two or more thereof. The amount of the electron-accepting dopant may vary depending on a material thereof. It is preferably in a range of 0.01 to 50% by mass, more preferably in a range of 0.05 to 20% by mass, and still more preferably in a range of 0.1 to 10% by mass, with respect to the materials constituting the hole transport layer or the hole injecting layer.

—Electron Injecting Layer and Electron Transport Layer—

The electron injecting layer and the electron transport layer are layers having the function of accepting electrons from the cathode or the cathode side and transporting them to the anode side. Specifically, the electron injecting layer and the electron transport layer are preferably layers containing a triazole derivative, an oxazole derivative, an oxadiazole derivative, an imidazole derivative, a fluorenone derivative, an anthraquinodimethane derivative, an anthrone derivative, a diphenylquinone derivative, a thiopyran dioxide derivative, a carbodiimide derivative, a fluorenylidenemethane derivative, a distyrylpyrazine derivative, an anhyride or imide of aromatic tetracarboxylic acid (examples of aromatic ring thereof include naphthalene and perylene), an anhydride or imide of aromatic dicarboxylic acid (examples of aromatic ring thereof include benzene and naphthalene), a phthalocyanine derivative, a metal complex of various kinds such as a metal complex of 8-quinolinol derivative, a metallophthalocyanine, or a metal complex having benzoxazole or benzothiazole as a ligand, an organic silane derivative or the like.

The thicknesses of the electron injecting layer and the electron transport layer are each preferably 50 nm or less from the viewpoint of lowering the driving voltage.

The thickness of the electron transport layer is preferably from 5 to 50 nm, and more preferably from 10 to 50 nm. Also, the thickness of the electron injecting layer is preferably from 0.1 to 50 nm, and more preferably from 0.5 to 20 nm.

The electron injecting layer and the electron transport layer may be of a single-layered structure comprising one or two or more types of the aforementioned materials, or may be of a multilayered structure consisting of a plurality of layers having the same composition or different compositions.

From the viewpoint of lowering the driving voltage of the element, the organic EL element of the invention may contain an electron-donating dopant in the electron injecting layer or the electron transport layer. Any materials may be used as the electron-donating dopant contained in the electron injecting layer or the electron transport layer as long as it has electron-donating properties and is capable of reducing organic compounds. Preferable examples of the electron-donating dopants include alkali metals such as Li, alkaline earth metals such as Mg, transition metals including rare earth metals, and reductive organic compounds. Metals having a work function of 4.2 eV or less may be preferably used. Specific examples thereof include Li, Na, K, Be, Mg, Ca, Sr, Ba, Y, Cs, La, Sm, Gd and Yb. Specific examples of the reductive organic compounds include nitrogen-containing compounds, sulfur-containing compounds and phosphorus-containing compounds.

Specific examples of the electron-donating dopants further include compounds described in JP-A Nos. 6-212153, 2000-196140, 2003-68468, 2003-229278, 2004-342614, the disclosures of which are incorporated by reference herein, and the like.

These electron-donating dopants may be used singly or in combination of two or more thereof. The amount of the electron-donating dopant may vary depending on a material thereof. It is preferably in a range of 0.1 to 99% by mass, more preferably in a range of 1.0 to 80% by mass, and still more preferably in a range of 2.0 to 70% by mass, with respect to the materials constituting the electron transport layer or the electron injecting layer.

<Protective Layer>

In the invention, the organic EL element as a whole may be protected by a protective layer.

The materials contained in the protective layer preferably have a function of preventing the factors which promote element deterioration such as moisture or oxygen from entering into the element.

Specific examples thereof include metals such as In, Sn, Pb, Au, Cu, Ag, Al, Ti, Ni or the like; metal oxides such as MgO, SiO, SiO₂, Al₂O₃, GeO, NiO, CaO, BaO, Fe₂O₃, Y₂O₃, TiO₂ or the like; metal nitrides such as SiNx, and SiNₓO_{y}; metal fluorides such as MgF₂, LiF, AlF₃, and CaF₂; polyethylene, polypropylene, polymethyl methacrylate, polyimide, polyurea, polytetrafluoroethylene, polychlorotrifluoroethylene, polydichlorodifluoroethylene, copolymers of chlorotrifluoroethylene and dichlorodifluoroethylene, copolymers obtainable by copolymerization of a monomer mixture including tetrafluoroethylene and at least one comonomer, fluorine-containing copolymers having a cyclic structure in the copolymer main chain, absorbent materials having a water-absorption rate of 1% or more, and moisture-resistant materials having a water-absorption rate of 0.1% or less.

The method for formation of the protective layer is not particularly limited. Example of the methods that can be used include a vacuum deposition method, a sputtering method, a reactive sputtering method, a MBE method (molecular beam epitaxy), a cluster ion beam method, an ion plating method, a plasma polymerization method (high frequency-excited ion plating), a plasma CVD method, a laser CVD method, a thermal CVD method, a gas source CVD method, a coating method, a printing method, and a transfer method.

<Sealing>

Moreover, the organic electroluminescent element of the invention may be sealed for the entire element using a sealing vessel.

Also, the space between the sealing vessel and the luminescent element may be filled with a moisture absorbent or an inert liquid. The moisture absorbent is not particularly limited. Examples of the moisture absorbent include barium oxide, sodium oxide, potassium oxide, calcium oxide, sodium sulfate, calcium sulfate, magnesium sulfate, phosphorous pentoxide, calcium chloride, magnesium chloride, copper chloride, cesium fluoride, niobium fluoride, calcium bromide, vanadium bromide, molecular sieves, zeolites, magnesium oxide and the like. The inert liquid is not particularly limited. Examples of the inert liquid include paraffins, liquid paraffins, fluorine type solvents such as perfluoroalkanes, perfluoroamines or perfluoroethers, chlorine type solvents, and silicone oils.

In the organic electroluminescent element of the invention, light emission can be obtained by applying a direct current (it may include an alternating current component, if desired) voltage (usually 2 to 15 V) or a direct current between the anode and the cathode.

As for the method of driving the organic electroluminescent element of the invention, the methods described in JP-A Nos. 2-148687, 6-301355, 5-29080, 7-134558, 8-234685 and 8-241047, Japanese Patent No. 2784615, and U.S. Pat. Nos. 5,828,429 and 6,023,308, the disclosures of which are incorporated by reference herein, and the like can be applied.

The organic EL element of the invention can be preferably applied in the fields of display elements, display devices, backlights, electrophotography, illuminating light sources, recording light sources, exposure light sources, reading light sources, sings, signboards, interiors, optical communications, and the like.

### EXAMPLES

The present invention is more specifically described below by showing examples, but the invention is not limited to these examples alone.

### Comparative Example 1

On a glass substrate of 0.5 mm in thickness and 2.5 cm square, using ITO target of In₂O₃ content of 95% by mass, an ITO thin film (thickness 0.2 μm) was formed as a transparent anode by DC magnetron sputtering (condition: base material temperature 100° C., oxygen pressure 1×10⁻³ Pa). Surface resistance of the ITO thin film was 10 Ω/sq.

The substrate having the transparent anode formed thereon was put in a washing container, was subjected to IPA washing, and then was subjected to UV ozone treatment for 30 minutes. On this transparent anode, a hole injecting layer of 10 nm was disposed by using copper phthalocyanine (CuPC) at a speed of 0.5 nm/sec by a vacuum deposition method.

Further thereon, a hole transport layer of 30 nm was disposed by using α-NPD ((N,N′-di-α-naphthyl-N,N′-diphenyl)-benzidine) at a speed of 0.5 nm/sec by a vacuum deposition method.

Moreover thereon, CBP as a host material in the luminescent layer, and Ir(ppy)₃ as a phosphorescent material in the luminescent layer, were co-deposited at a ratio of 100/5 by a vacuum deposition method to form a luminescent layer of 30 nm.

On the luminescent layer, compound (a) shown below was deposited at a speed of 0.5 nm/sec by a vacuum deposition method to form a hole blocking layer of 10 nm, and further thereon Alq₃ as an electron transport material was deposited at a speed of 0.2 nm/sec by a vacuum deposition method to form an electron injecting layer of 40 nm. The ionization potential of the single layer of the compound (a) measured by a UPS method was 7.1 eV.

On the electron injecting layer, moreover, a patterned mask (such a mask as to give a luminescent area of 2 mm×2 mm) was placed, and lithium fluoride was deposited to a thickness of 1 nm by a vacuum deposition method. Aluminum was further deposited thereon by a vacuum deposition method to form a cathode of 0.1 μm.

The obtained luminescent laminated product was put in a glove box in which air was replaced with a nitrogen gas, and then sealed by using a stainless steel-made sealing can having a desiccant provided therein as well as an ultraviolet-curable adhesive (XNR5516HV, manufactured by Nagase ChemteX Corporation) to obtain a luminescent element of comparative example 1.

The operation from the deposition of copper phthalocyanine until the sealing was performed in vacuum or a nitrogen atmosphere to produce the element without any exposure to air.

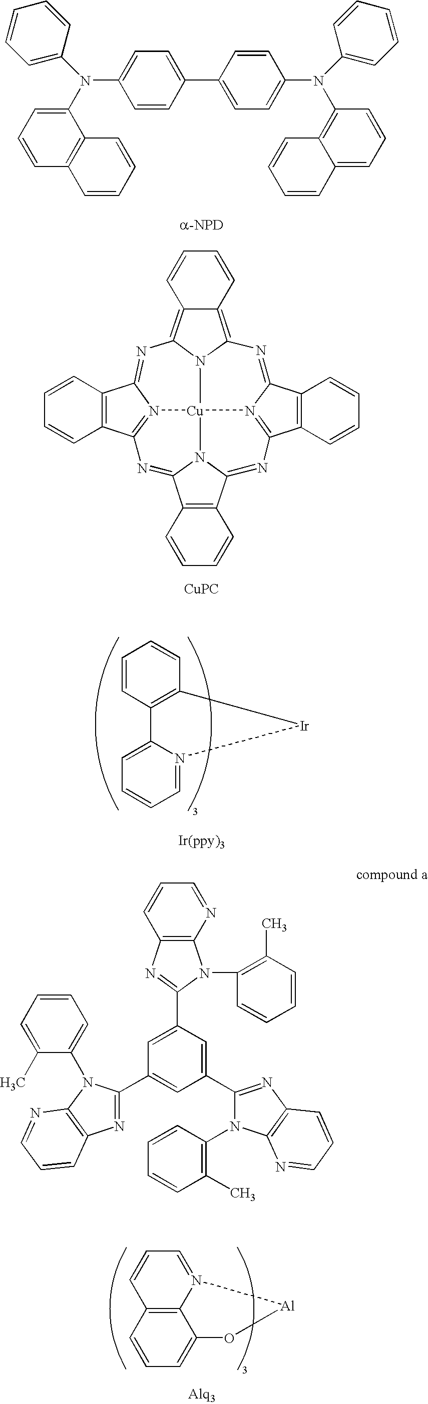

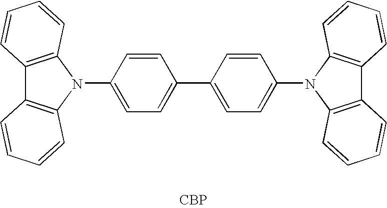

[Evaluation]

The ionization potential (Ip) and the electron mobility of the electron transport material and the phosphorescent material in the hole blocking layer were measured in terms of a single layer film (independent layer) of each material. Using the luminescent element obtained above, the driving durability was measured by the following method. The results obtained are shown in Table 1.

(1) Driving Durability

A continuous driving test was conducted at current density of 10 mA/cm² and the time period until the luminance was decreased to half of the initial value was determined as a luminance half-life T(½) and the driving durability was evaluated.

### Example 1

A luminescent element was manufactured and evaluated in the same manner as in comparative example 1, except that the hole blocking layer of 10 nm was obtained by co-depositing compound (a) as an electron transport material and Ir(ppy)₃ as a phosphorescent material at a ratio of 100:5 by a vacuum deposition method. The results are shown in Table 1.

### Example 2

A luminescent element was manufactured and evaluated in the same manner as in example 1, except that the ratio of co-deposition of compound (a) and Ir(ppy)₃ in the hole blocking layer was changed to 100:12. The results are shown in Table 1.

TABLE 1

| | | Comparative | | |
|---|---|---|---|---|
| | | Example 1 | Example 1 | Example 2 |
| Hole injecting/transport layer | | CuPc/NPD | CuPc/NPD | CuPc/NPD |
| Luminescent layer | Host | CBP | CBP | CBP |
| | Phosphorescent material | Ir(ppy)₃ | Ir(ppy)₃ | Ir(ppy)₃ |
| Hole blocking layer | Electron transport material | Compound a | Compound a | Compound a |
| | Phosphorescent material | — | Ir(ppy)₃ | Ir(ppy)₃ |
| Ratio of electron transport material and phosphorescent | | — | 100:5 | 100:12 |
| material in hole blocking layer | | | | |
| Thickness of hole blocking layer (nm) | | 10 | 10 | 10 |
| Electron mobility of electron transport material of | | 9 × 10⁻⁴ | 9 × 10⁻⁴ | 9 × 10⁻⁴ |
| hole blocking layer (cm²/Vs) | | | | |
| IP (ET): IP of electron transport material of hole blocking layer (eV) | | 7.1 | 7.1 | 7.1 |
| IP (HT): IP of phosphorescent material of hole blocking layer (eV) | | — | 5.4 | 5.4 |
| IP (ET) − IP(HT) | | — | 1.7 | 1.7 |
| Durability @ 10 mA/cm² | Initial luminance in driving test (cd/m²) | 3100 | 3300 | 2700 |
| | Luminance half-life (hours) | 80 | 190 | 300 |

| | | | |
|---|---|---|---|
| Luminescent efficiency (cd/A) @ 10 mA/cm² | 31 | 33 | 27 |

As seen in Table 1, the electroluminescent element of the invention can enhance driving durability of the element without lowering luminescent efficiency.

As described herein, the invention provides an organic electroluminescent element excellent in driving durability without lowering luminescent efficiency.

What is claimed is:

1. An organic electroluminescent element comprising, between an anode and a cathode, at least a luminescent layer and a hole blocking layer that is adjacent to the cathode side of the luminescent layer, wherein the luminescent layer comprises a phosphorescent material and a host material, the hole blocking layer comprises a phosphorescent material and an electron transport material, the phosphorescent material contained in the luminescent layer and the hole blocking layer is the same, and the ionization potential IP (ET) of the electron transport material contained in the hole blocking layer is greater than the ionization potential IP (EM) of the phosphorescent material by 1 eV or more.

2. The organic electroluminescent element of claim 1, wherein the ionization potential IP (ET) of the electron transport material contained in the hole blocking layer is 6.3 eV or more.

3. The organic electroluminescent element of claim 1, wherein the electron transport material contained in the hole blocking layer is represented by formula (A-1) or (B-1): 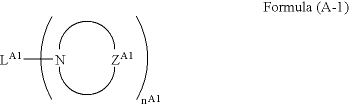
wherein Z^{A1} represents an atomic group necessary for forming a nitrogen-containing heterocycle, L^{A1} is a linking group, and n^{A1} is an integer of 2 or more; 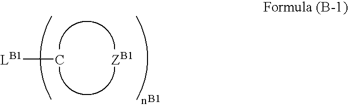
wherein Z^{B1} represents an atomic group necessary for forming an aromatic hydrocarbon ring or an aromatic heterocycle, L^{B1} is a linking group, and n is an integer of 2 or more.

4. The organic electroluminescent element of claim 3, wherein L^{A1} is a linking group selected from the group consisting of a single bond, a carbon atom, a silicon atom, a boron atom, an oxygen atom, a sulfur atom, a germanium atom, an aromatic hydrocarbon ring, and an aromatic heterocycle.

5. The organic electroluminescent element of claim 3, wherein L^{A1} is a linking group selected from the group consisting of a 1,3,5-benzene triyl group, a 1,2,5,6-benzene tetrayl group, a 1,2,3,4,5,6-benzene hexayl group, a 2,2′-dimethyl-4,4′-biphenylene group, a 2,4,6-pyridine triyl group, a 2,3,4,5,6-pyridine pentayl group, a 2,4,6-pyrimidine triyl group, a 2,4,6-triazine triyl group, and a 2,3,4,5-thiophene tetrayl group.

6. The organic electroluminescent element of claim 3, wherein L^{B1} is a linking group selected from the group consisting of a single bond, a di- or higher-valent aromatic hydrocarbon ring, a di- or higher-valent aromatic heterocycle, a carbon atom, a nitrogen atom, and a silicon atom.

7. The organic electroluminescent element of claim 3, wherein L^{B1} is a linking group selected from the group consisting of a 1,3,5-benzene triyl group, a 1,2,5,6-benzene tetrayl group, a 1,2,3,4,5,6-benzene hexayl group, a 2,2′-dimethyl-4,4′-biphenylene group, a 2,4,6-pyridine triyl group, a 2,3,4,5,6-pyridine pentayl group, a 2,4,6-pyrimidine triyl group, a 2,4,6-triazine triyl group, a 2,3,4,5-thiophene tetrayl group, a carbon atom, a nitrogen atom, and a silicon atom.

8. The organic electroluminescent element of claim 1, wherein the electron transport material contained in the hole blocking layer contains three or more nitrogen atoms.

9. The organic electroluminescent element of claim 3, wherein the electron transport material contained in the hole blocking layer contains three or more nitrogen atoms.

10. The organic electroluminescent element of claim 1, wherein the host material contained in the luminescent layer has a carbazole group.

11. The organic electroluminescent element of claim 1, wherein a content of the phosphorescent material in the luminescent layer is 0.1 to 20% by mass.

12. The organic electroluminescent element of claim 1, wherein a content of the host material in the luminescent layer is 50 to 99.9% by mass.

13. The organic electroluminescent element of claim 1, wherein the electron transport material contained in the hole blocking layer is an azole compound or an azine compound.

14. The organic electroluminescent element of claim 1, wherein a content of the phosphorescent material in the hole blocking layer is 0.1 to 30% by mass.

15. The organic electroluminescent element of claim 1, wherein a content of the electron transport material in the hole blocking layer is 50 to 99.9% by mass.

16. The organic electroluminescent element of claim 1, wherein the electron mobility of the electron transport material contained in the hole blocking layer is 1×10⁻⁵ cm²/Vs or more.
